(19) United States
(12) Patent Application Publication
(10) Pub. No.: US 2017/0181335 A1
(43) Pub. Date: Jun. 22, 2017

(54) SHIELD COVER AND ELECTRONIC APPARATUS

(71) Applicant: Panasomic Intellectual Property Management Co., Ltd., Osaka (JP)

(72) Inventor: TOMOHIKO ITOU, Osaka (JP)

(21) Appl. No.: 15/327,107

(22) PCT Filed: Sep. 18, 2015
(86) PCT No.: PCT/JP2015/004788

§ 371 Date: Jan. 18, 2017

(30) Foreign Application Priority Data
Sep. 30, 2014 (JP) 2014-201742

(51) Int. Cl. H05K 9/00; H05K 1/02; H05K 1/18

(52) U.S. Cl. CPC H05K 9/0024; H05K 1/181; H05K 1/0203; H05K 2201/06; H05K 2201/10371

(57) ABSTRACT

A shield cover includes a cover body that is formed of a metal plate and for covering an electronic component, a leaf spring formed by cutting a part of the cover body, and a projection that is disposed on the leaf spring and projects in the thickness direction of the leaf spring.

### TECHNICAL FIELD

The present disclosure relates to a shield cover and electronic apparatus for blocking electromagnetic waves emitted from an electronic component.

### BACKGROUND ART

Generally, a substrate on which an electronic component such as an integrated circuit (IC) is mounted is disposed in an electronic apparatus such as a liquid crystal television (TV) receiver. The influence of electromagnetic waves emitted from such an electronic component on another electronic apparatus is called electromagnetic interference (EMI).

Patent Literature 1 discloses a shield cover for blocking electromagnetic waves emitted from an electronic component to take measures against the EMI. The shield cover is attached to a substrate in the electronic apparatus so as to cover the electronic component. Another member such as a gasket is sandwiched between the shield cover and the chassis of the electronic apparatus. The gasket is configured by covering the surroundings of a sponge-like core material with a conductive coating material such as a metal foil. By electrically connecting the shield cover to the chassis of the electronic apparatus via the gasket or the like, the blocking performance of the shield cover is improved.

### CITATION LIST

### Patent Literature

PTL 1: Japanese Patent No. 5233677

### SUMMARY

The present disclosure provides a shield cover and electronic apparatus capable of improving the performance (hereinafter referred to as “blocking performance”) of blocking electromagnetic waves emitted from an electronic component without using another member such as a gasket.

The shield cover of the present disclosure is a shield cover for blocking the electromagnetic waves emitted from the electronic component. The shield cover includes a cover body that is formed of a metal plate and covers the electronic component, a leaf spring formed by cutting a part of the cover body, and a projection that is disposed on the leaf spring and projects in the thickness direction of the leaf spring.

The shield cover of the present disclosure can improve the blocking performance without using another member such as a gasket.

### BRIEF DESCRIPTION OF DRAWINGS

FIG. 1 is a perspective view showing one example of the appearance of an electronic apparatus in accordance with a first exemplary embodiment.

FIG. 2 is an exploded perspective view showing one example of the shield structure in accordance with the first exemplary embodiment.

FIG. 3 is a plan view showing the one example of the shield structure in accordance with the first exemplary embodiment.

FIG. 4 is a sectional view of the shield structure taken along line A-A of FIG. 3.

FIG. 5 is a sectional view of the shield structure taken along line B-B of FIG. 3.

FIG. 6 is an enlarged perspective view of a leaf spring of a shield cover in accordance with the first exemplary embodiment.

FIG. 7 is a sectional view of the leaf spring taken along line C-C of FIG. 3.

FIG. 8 is a sectional view showing the state when a projection abuts on a chassis from the state of FIG. 7.

FIG. 9 is an enlarged perspective view of a leaf spring of a modified example in accordance with the first exemplary embodiment.

### DESCRIPTION OF EMBODIMENTS

Hereinafter, the exemplary embodiments will be described in detail appropriately with reference to the accompanying drawings. Description more detailed than necessary is sometimes omitted. For example, a detailed description of a well-known item and a repeated description of substantially the same configuration are sometimes omitted. This is for the purpose of preventing the following descriptions from becoming more redundant than necessary and allowing persons skilled in the art to easily understand the exemplary embodiments.

The accompanying drawings and the following descriptions are provided to allow the persons skilled in the art to sufficiently understand the present disclosure. It is not intended that they restrict the main subject described within the scope of the claims.

Each diagram is a schematic diagram, and is not always exact. In each diagram, the same components are denoted with the same reference marks.

### First Exemplary Embodiment

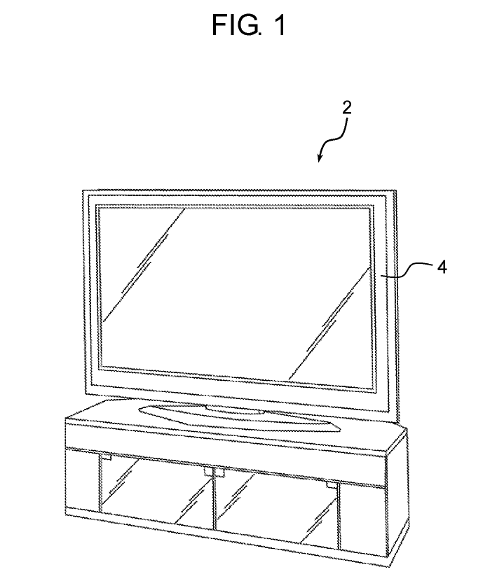

The first exemplary embodiment is hereinafter described using FIG. 1 to FIG. 8.

[1-1. Configuration of Electronic Apparatus]

First, the configuration of electronic apparatus 2 is described with reference to FIG. 1 to FIG. 4.

FIG. 1 is a perspective view showing one example of the appearance of electronic apparatus 2 in accordance with the first exemplary embodiment.

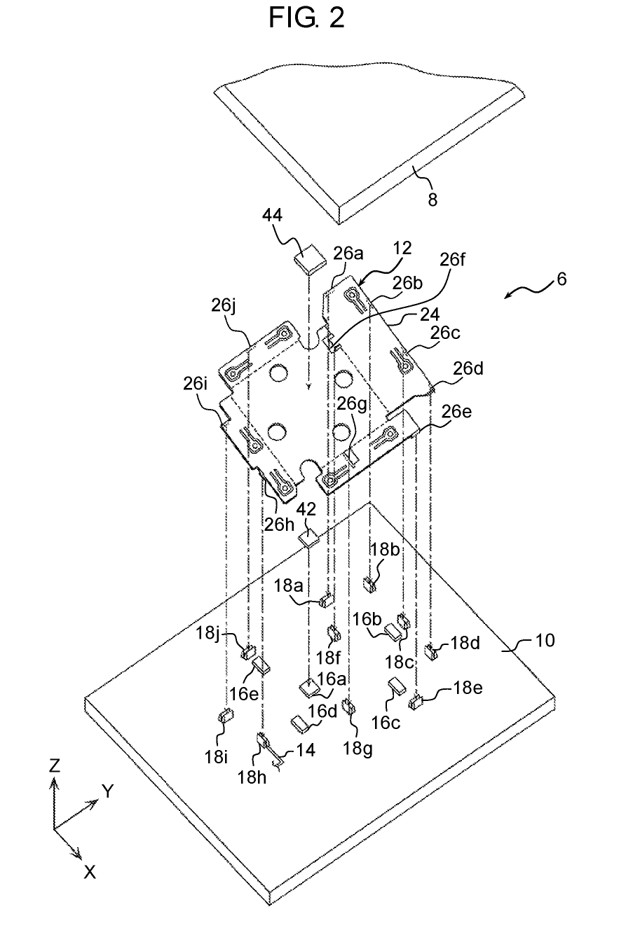

FIG. 2 is an exploded perspective view showing one example of shield structure 6 in accordance with the first exemplary embodiment.

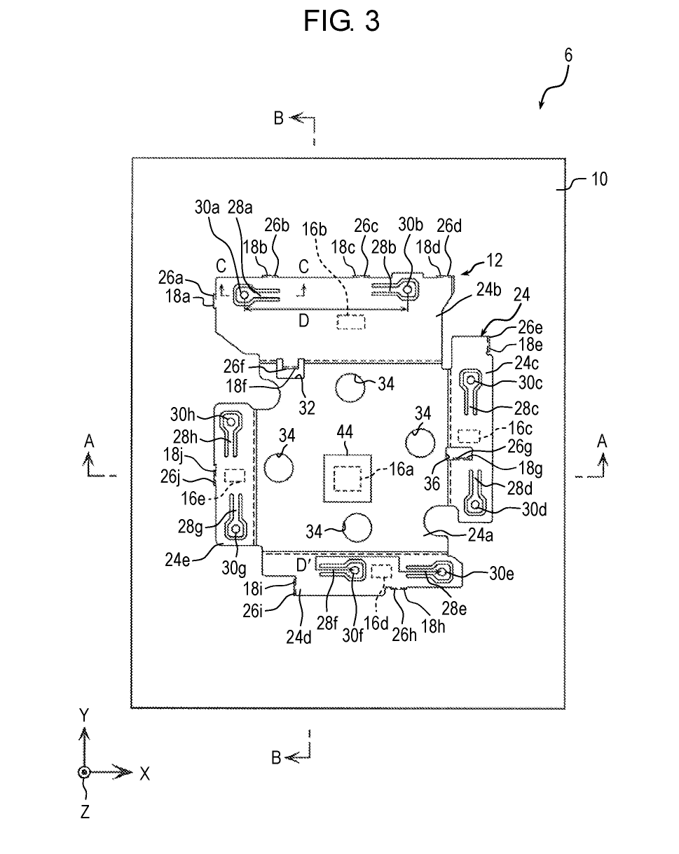

FIG. 3 is a plan view showing the one example of shield structure 6 in accordance with the first exemplary embodiment.

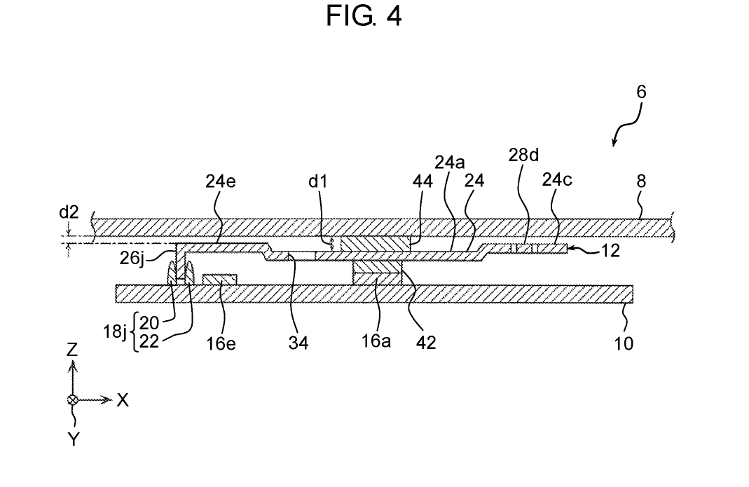

FIG. 4 is a sectional view of shield structure 6 taken along line A-A of FIG. 3. In FIG. 3, chassis 8 is omitted.

Electronic apparatus 2 is an apparatus including an electronic component emitting electromagnetic waves. FIG. 1 shows a liquid crystal TV receiver as one example of electronic apparatus 2. Electronic apparatus 2 is not limited to the liquid crystal TV receiver, but may be any apparatus as long as the apparatus includes an electronic component emitting electromagnetic waves.

Shield structure 6 shown in FIG. 2 to FIG. 4 is disposed in casing 4 of electronic apparatus 2. Shield structure 6 includes chassis 8, substrate 10, and shield cover 12.

Chassis 8 is a metal plate for supporting a backlight unit or the like (not shown), for example. Chassis 8 is formed of a metal such as a steel electrolytic cold commercial (SECC) (Steel Electrolytic Cold Commercial: zinc-coated steel plate), for example. Chassis 8 is electrically connected to ground wiring 14 disposed on substrate 10. Thus, the potential of chassis 8 is equal to the ground potential.

As shown in FIG. 2 and FIG. 4, substrate 10 is disposed at a position facing chassis 8. On the surface of substrate 10 on the side facing chassis 8, printed wiring such as ground wiring 14 is disposed, and a plurality of IC 16a to IC 16e (IC 16a, IC 16b, IC 16c, IC 16d, and IC 16e) are mounted. Each of IC 16a to IC 16e is one example of an electronic component.

Each of the plurality of IC 16a to IC 16e is a memory IC operating at a high frequency of about 1 GHz, for example. Although not shown, on substrate 10, in addition to the plurality of IC 16a to IC 16e, various electronic components such as a capacitor and a resistor element are mounted, for example. On substrate 10, an IC for signal processing or an IC for control may be mounted.

On the surface of substrate 10 on the side facing chassis 8, furthermore, a plurality of metal contact clip 18a to contact clip 18j are mounted. Contact clip 18a to contact clip 18j mean contact clip 18a, contact clip 18b, contact clip 18c, contact clip 18d, contact clip 18e, contact clip 18f, contact clip 18g, contact clip 18h, contact clip 18i, and contact clip 18j.

Each of the plurality of contact clip 18a to contact clip 18j is electrically connected to ground wiring 14 disposed on substrate 10. Thus, the potential of each of the plurality of contact clip 18a to contact clip 18j is equal to the ground potential. In other words, each of the plurality of contact clip 18a to contact clip 18j is one example of a ground potential portion.

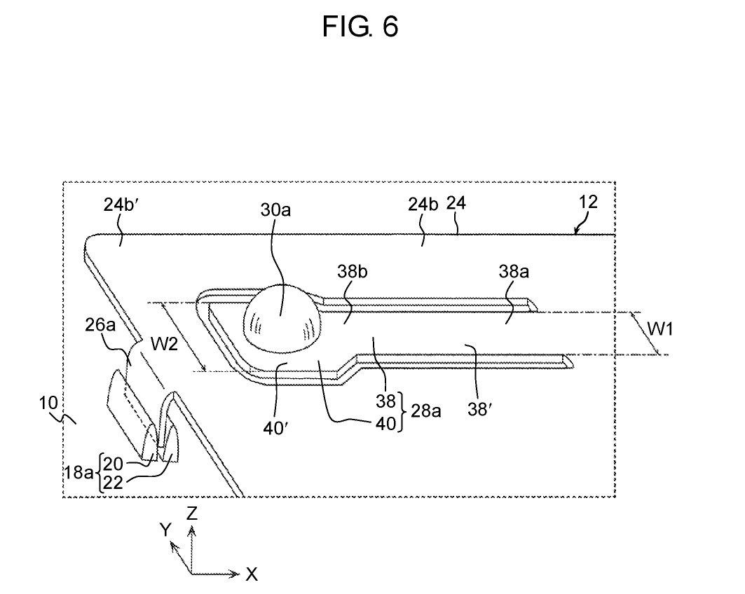

As shown in FIG. 4 and FIG. 6 described later, each of the plurality of contact clip 18a to contact clip 18j includes a pair of clip portion 20 and clip portion 22 having an elastic force. The pair of clip portion 20 and clip portion 22 are disposed close to each other, and another member may be elastically sandwiched between the pair of clip portion 20 and clip portion 22.

Shield cover 12 is a metal plate for taking measures against the EMI by blocking the electromagnetic waves emitted from each of the plurality of IC 16a to IC 16e. Shield cover 12 is made of a metal such as aluminum, for example. Shield cover 12 is not limited to aluminum, but may be made of another metal.

As shown in FIG. 2 to FIG. 4, shield cover 12 is mounted on substrate 10 so as to cover the plurality of IC 16a to IC 16e. In other words, shield cover 12 is disposed between chassis 8 and substrate 10. Shield cover 12 is electrically connected to ground wiring 14 disposed on substrate 10, and is electrically connected to chassis 8. Thus, the potential of shield cover 12 is equal to the ground potential. The configuration of shield cover 12 is described later.

[1-2. Configuration of Shield Cover]

Next, the configuration of shield cover 12 is described with reference to FIG. 2 to FIG. 8.

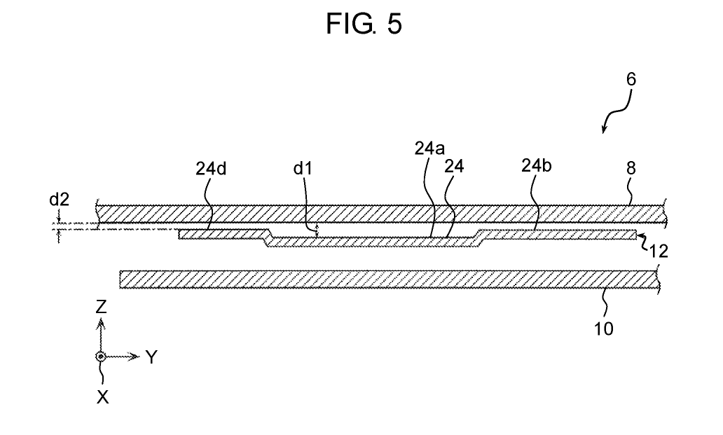

FIG. 5 is a sectional view of shield structure 6 taken along line B-B of FIG. 3.

FIG. 6 is an enlarged perspective view of leaf spring 28a of shield cover 12 in accordance with the first exemplary embodiment.

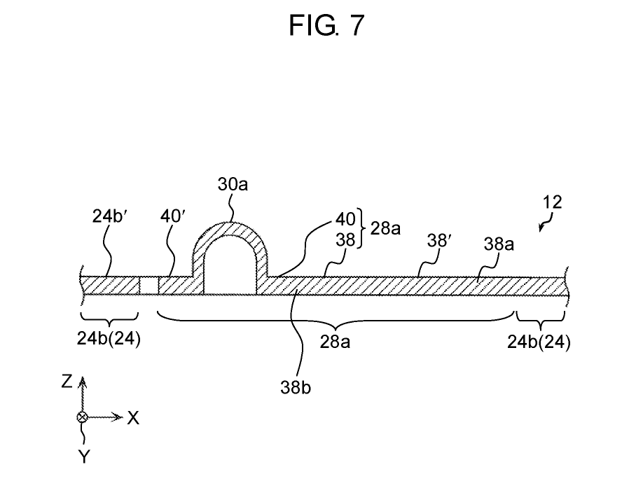

FIG. 7 is a sectional view of leaf spring 28a taken along line C-C of FIG. 3.

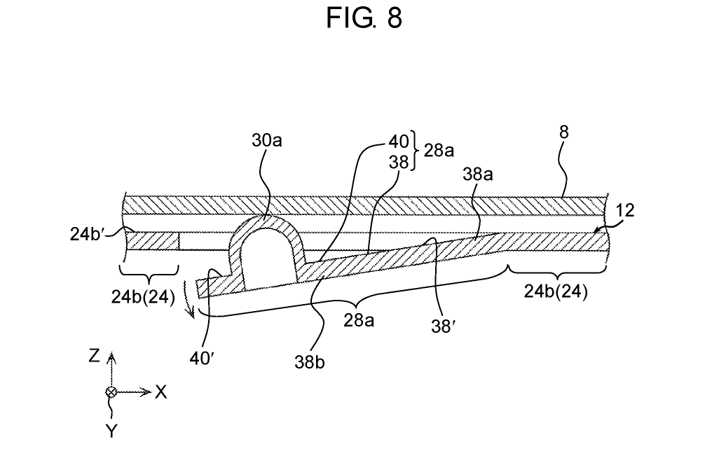

FIG. 8 is a sectional view showing the state when projection 30a abuts on chassis 8 from the state of FIG. 7.

As shown in FIG. 2 and FIG. 3, shield cover 12 includes the following elements:
cover body 24;
a plurality of attachment portion 26a to attachment portion 26j (attachment portion 26a, attachment portion 26b, attachment portion 26c, attachment portion 26d, attachment portion 26e, attachment portion 26f, attachment portion 26g, attachment portion 26h, attachment portion 26i, and attachment portion 26j);
a plurality of leaf spring 28a to leaf spring 28h (leaf spring 28a, leaf spring 28b, leaf spring 28c, leaf spring 28d, leaf spring 28e, leaf spring 28f, leaf spring 28g, and leaf spring 28h); and
a plurality of projection 30a to projection 30h (projection 30a, projection 30b, projection 30c, projection 30d, projection 30e, projection 30f, projection 30g, and projection 30h).
   Shield cover 12 is formed by pressing one sheet metal, for example.

Cover body 24 includes first body 24a, second body 24b, third body 24c, fourth body 24d, and fifth body 24e. First body 24a is formed in a substantially rectangular shape. The four edges of first body 24a are connected to second body 24b, third body 24c, fourth body 24d, and fifth body 24e, respectively. Second body 24b, third body 24c, fourth body 24d, and fifth body 24e are extended laterally along respective edges of first body 24a.

As shown in FIG. 4 and FIG. 5, the boundary between first body 24a and each of second body 24b to fifth body 24e is formed in a step shape. Thus, the height level of each of second body 24b to fifth body 24e in the Z-axis direction (Z-axis direction shown in the drawings) is higher than that of first body 24a in the Z-axis direction. Each broken line in FIG. 2 and FIG. 3 shows the step shape in the boundary between first body 24a and each of second body 24b to fifth body 24e.

As shown in FIG. 3, first body 24a includes a substantially U-shaped cutout 32 for forming attachment portion 26f. Furthermore, first body 24a includes a plurality of circular cutouts 34 at arrangement positions of screws so that the screws (not shown) fastened to chassis 8 do not abut on first body 24a.

Third body 24c includes a substantially rectangular cutout 36 for forming attachment portion 26g.

As shown in FIG. 2 and FIG. 3, each of the plurality of attachment portion 26a to attachment portion 26j is disposed so as to extend from cover body 24 toward substrate 10. Each of the plurality of attachment portion 26a to attachment portion 26d is disposed on the periphery of second body 24b. Attachment portion 26e is disposed on the periphery of third body 24c. Attachment portion 26f is disposed on the periphery of cutout 32. Attachment portion 26g is disposed on the periphery of cutout 36. Each of attachment portion 26h and attachment portion 26i is disposed on the periphery of fourth body 24d. Attachment portion 26j is disposed on the periphery of fifth body 24e.

The plurality of attachment portion 26a to attachment portion 26j are detachably attached to the plurality of contact clip 18a to contact clip 18j mounted on substrate 10, respectively. As shown in FIG. 6, for example, attachment portion 26a is elastically sandwiched between the pair of clip portion 20 and clip portion 22 of contact clip 18a. Thus, shield cover 12 is attached to substrate 10. The plurality of attachment portion 26a to attachment portion 26j are electrically connected to the plurality of contact clip 18a to contact clip 18j, respectively, so that shield cover 12 is electrically connected to ground wiring 14 disposed on substrate 10.

As shown in FIG. 3, FIG. 6, and FIG. 7, each of the plurality of leaf spring 28a to leaf spring 28h is formed by cutting a part of cover body 24 in a slit shape. A pair of leaf spring 28a and leaf spring 28b are disposed at a distance from each other along the longitudinal direction of second body 24b (X-axis direction shown in the drawings). A pair of leaf spring 28c and leaf spring 28d are disposed at a distance from each other along the longitudinal direction of third body 24c (Y-axis direction shown in the drawings). A pair of leaf spring 28e and leaf spring 28f are disposed at a distance from each other along the longitudinal direction of fourth body 24d (X-axis direction). A pair of leaf spring 28g and leaf spring 28h are disposed at a distance from each other along the longitudinal direction of fifth body 24e (Y-axis direction).

Leaf spring 28a is disposed near attachment portion 26a and attachment portion 26b, and leaf spring 28b is disposed near attachment portion 26c and attachment portion 26d. Leaf spring 28c is disposed near attachment portion 26e, and leaf spring 28d is disposed near attachment portion 26g. Leaf spring 28e is disposed near attachment portion 26h, and leaf spring 28f is disposed near attachment portion 26i. Each of leaf spring 28g and leaf spring 28h is disposed near attachment portion 26j.

Each of the plurality of leaf spring 28a to leaf spring 28h has substantially the same shape. Therefore, the shape of leaf spring 28a, of the plurality of leaf spring 28a to leaf spring 28h, is hereinafter described, and the descriptions of other leaf spring 28b to leaf spring 28h are omitted.

As shown in FIG. 3, FIG. 6, and FIG. 7, leaf spring 28a includes connection portion 38 and expanded portion 40. Connection portion 38 linearly extends in a predetermined direction from first end 38a to second end 38b. Here, the direction from first end 38a to second end 38b is referred to as the predetermined direction. In the example shown in FIG. 6, the predetermined direction is set as X-axis direction. First end 38a of connection portion 38 is connected to second body 24b, and second end 38b of connection portion 38 is connected to expanded portion 40. Width W2 of expanded portion 40 in the direction (namely, Y-axis direction) substantially perpendicular to the predetermined direction is greater than width W1 of connection portion 38 in the direction (namely, Y-axis direction) substantially perpendicular to the predetermined direction.

As shown in FIG. 6 and FIG. 7, in a state where a force in the thickness direction (Z-axis direction) is not applied to leaf spring 28a, each of surface 38′ of connection portion 38 and surface 40′ of expanded portion 40 is disposed on substantially the same plane as surface 24b′ of second body 24b.

As shown in FIG. 8, when a force in the thickness direction (Z-axis direction) is applied to leaf spring 28a, leaf spring 28a elastically bends downward with first end 38a of connection portion 38 as a fixed end (namely, in the minus direction on the Z-axis). Thus, each of surface 38′ of connection portion 38 and surface 40′ of expanded portion 40 is disposed below surface 24b′ of second body 24b (in the minus direction on the Z-axis).

As shown in FIG. 3, the pair of leaf spring 28a and leaf spring 28b are arranged so that their expanded portions 40 point in the opposite directions with each other. The direction of a leaf spring means the arrangement direction from the first end to the expanded portion. For example, the direction of leaf spring 28a means the arrangement direction from first end 38a of leaf spring 28a to expanded portion 40 of leaf spring 28a.

The pair of leaf spring 28c and leaf spring 28d and the pair of leaf spring 28g and leaf spring 28h are respectively arranged in a similar manner. While, the pair of leaf spring 28e and leaf spring 28f are arranged so that their expanded portions 40 point in the same direction.

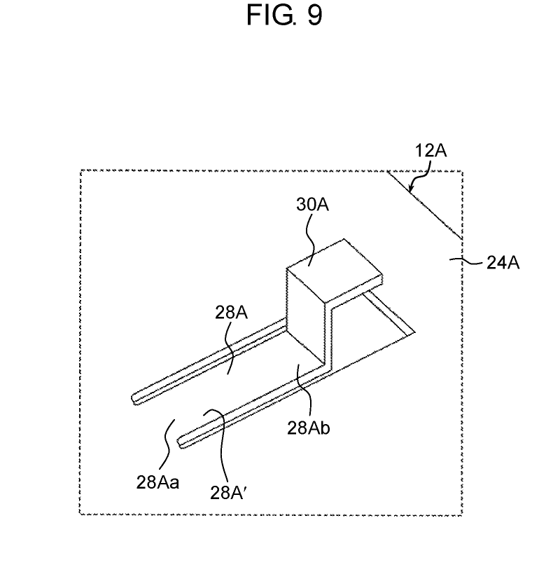

As shown in FIG. 3, FIG. 6, and FIG. 7, each of the plurality of projection 30a to projection 30h is disposed on surface 40′ of expanded portion 40 of each of the plurality of leaf spring 28a to leaf spring 28h in a projecting shape in the thickness direction (Z-axis direction) of each of leaf spring 28a to leaf spring 28h. Here, each surface 40′ is on the opposite side to the surface facing each of the plurality of IC 16a to IC 16e. Each of the plurality of projection 30a to projection 30h is formed in a substantially hemispherical shape, for example. The height of each of the plurality of projection 30a to projection 30h from surface 40′ of expanded portion 40 is about 0.5 mm, for example. The shape of each of projection 30a to projection 30h is not limited to a hemisphere, but may be another shape. One example of another shape is described later as a modified example using FIG. 9. The height of each of projection 30a to projection 30h is not limited to this numerical value.

Arrangement interval D (FIG. 3) between projection 30a and projection 30b of the pair of leaf spring 28a and leaf spring 28b is configured to be shorter than the quarter wavelength of a signal of a predetermined frequency used in each of the plurality of IC 16a to IC 16e.

For example, when each of the plurality of IC 16a to IC 16e operates at a frequency of about 1 GHz, the arrangement interval D between the pair of projection 30a and projection 30b is shorter than 75 mm The wavelength of electromagnetic waves of 1 GHz is about 300 mm.

This configuration is employed to improve the function of making the pair of leaf spring 28a and leaf spring 28b serve as antennas and suppressing the emission of the electromagnetic waves.

Similarly to the above-mentioned configuration, the pair of leaf spring 28c and leaf spring 28d are also configured so that the arrangement interval between projection 30c and projection 30d is shorter than the quarter wavelength of the signal of the predetermined frequency used in each of the plurality of IC 16a to IC 16e. Similarly, the pair of leaf spring 28g and leaf spring 28h are also configured so that the arrangement interval between projection 30g and projection 30h is shorter than the quarter wavelength of the signal of the predetermined frequency used in each of the plurality of IC 16a to IC 16e.

As discussed above, the pair of leaf spring 28e and leaf spring 28f are arranged so that their expanded portions 40 point in the same direction. Regarding the pair of leaf spring 28e and leaf spring 28f, therefore, arrangement interval D′ (FIG. 3) between projection 30e and projection 30f is the length along the surface of fourth body 24d (the length of the double-headed arrow line shown by D′ in FIG. 3). Arrangement interval D′ between the pair of projection 30e and projection 30f is also configured to be shorter than the quarter wavelength of the signal of the predetermined frequency used in each of the plurality of IC 16a to IC 16e.

As shown in FIG. 4 and FIG. 5, in the state where above-mentioned shield cover 12 is mounted on substrate 10, shield cover 12 is disposed near chassis 8. For example, interval d1 between first body 24a and chassis 8 is about 0.5 mm, and interval d2 between each of second body 24b to fifth body 24e and chassis 8 is about 0.3 mm Here, interval d1 and interval d2 are not limited to these numerical values.

Each of the plurality of projection 30a to projection 30h projects toward chassis 8 from surface 40′ of each expanded portion 40, as shown in FIG. 8. Therefore, in the state where shield cover 12 is mounted on substrate 10, each of the plurality of projection 30a to projection 30h abuts on the surface of chassis 8 and is pressed down. Thus, each of the plurality of leaf spring 28a to leaf spring 28h receives a force in the thickness direction from chassis 8, and elastically bends downward (in the minus direction on the Z-axis). Each of the plurality of projection 30a to projection 30h abuts on chassis 8 and is electrically connected to it, so that shield cover 12 is electrically connected to chassis 8.

As shown in FIG. 3, in the state where shield cover 12 is mounted on substrate 10, first body 24a to fifth body 24e are arranged so as to cover the plurality of IC 16a to IC 16e, respectively. As shown in FIG. 2 and FIG. 4, thermal conductive rubber 42 is sandwiched between IC 16a and first body 24a in the state where thermal conductive rubber 42 is compressed in the Z-axis direction. Furthermore, thermal conductive rubber 44 is sandwiched between first body 24a and chassis 8 in the state where thermal conductive rubber 44 is compressed in the Z-axis direction. Thermal conductive rubber 42 is one example of a first thermal conductive member, and thermal conductive rubber 44 is one example of a second thermal conductive member. Each of thermal conductive rubber 42 and thermal conductive rubber 44 is urethane rubber, acrylic rubber, or fluorine rubber containing filler metal, for example. The thickness of each of thermal conductive rubber 42 and thermal conductive rubber 44 in the Z-axis direction in the non-compressed state is about 1 mm, for example. However, the thickness of each of thermal conductive rubber 42 and thermal conductive rubber 44 is not limited to this numerical value.

(Modified Example of First Exemplary Embodiment)

Next, a modified example of the first exemplary embodiment is described with reference to FIG. 9.

FIG. 9 is an enlarged perspective view of leaf spring 28A of the modified example in accordance with the first exemplary embodiment.

In shield cover 12A of the modified example, the shapes of leaf spring 28A and projection 30A are different from those of each of leaf spring 28a to leaf spring 28h and each of projection 30a to projection 30h described in the first exemplary embodiment.

As shown in FIG. 9, leaf spring 28A linearly extends in a predetermined direction from first end 28Aa to second end 28Ab. Here, the direction from first end 28Aa to second end 28Ab is referred to as the predetermined direction.

First end 28Aa of leaf spring 28A is connected to cover body 24A, and second end 28Ab of leaf spring 28A is connected to projection 30A. Projection 30A is formed so as to project in a substantially L-shape from surface 28A′ of leaf spring 28A in the thickness direction of leaf spring 28A (in the same direction as that of substantially hemispherical projection 30a shown in FIG. 7 and FIG. 8).

Also when projection 30A is formed in such a shape, advantageous effect similar to that of the first exemplary embodiment can be produced.

[1-3. Advantageous Effect or the Like]

Thus, the shield cover of the present exemplary embodiment is a shield cover for blocking an electromagnetic wave emitted from an electronic component.

The shield cover includes a cover body that is formed of a metal plate and covers the electronic component, a leaf spring that is formed by cutting a part of the cover body, and a projection that is disposed on the leaf spring and projects in the thickness direction of the leaf spring.

The electronic apparatus of the present exemplary embodiment includes a metal chassis, a substrate that is disposed so as to face the chassis, an electronic component that is mounted on the substrate, and a shield cover that is disposed between the chassis and substrate and blocks electromagnetic waves emitted from the electronic component. The shield cover includes a cover body that is formed of a metal plate and is mounted on the substrate so as to cover the electronic component, a leaf spring that is formed by cutting a part of the cover body, and a projection that is disposed so as to project from the leaf spring toward the chassis and abuts on the chassis.

Shield cover 12 is one example of the shield cover. Each of IC 16a to IC 16e is one example of the electronic component. Each of cover body 24 and cover body 24A is one example of the cover body. Each of leaf spring 28a to leaf spring 28h and leaf spring 28A is one example of the leaf spring. Each of projection 30a to projection 30h and projection 30A is one example of the projection. Electronic apparatus 2 is one example of the electronic apparatus. Chassis 8 is one example of the chassis. Substrate 10 is one example of the substrate.

Thus, electromagnetic waves emitted from the electronic component (in the configuration example shown in the first exemplary embodiment, each of IC 16a to IC 16e) can be blocked by the shield cover (in the configuration example shown in the first exemplary embodiment, shield cover 12). Therefore, the electronic apparatus (in the configuration example shown in the first exemplary embodiment, electronic apparatus 2) including the shield cover can take measures against the EMI by blocking the electromagnetic waves leaking from the internal electronic component to the outside.

For example, in the configuration example shown in the first exemplary embodiment, the following configuration is employed as discussed above:
in the state where shield cover 12 is mounted on substrate 10, each of the plurality of projection 30a to projection 30h abuts on chassis 8 and is pressed down, and hence shield cover 12 is electrically connected to chassis 8. Thus, the potential of shield cover 12 can be kept stable at the ground potential without using another member such as a gasket, so that the blocking performance of shield cover 12 can be improved.

In this shield cover, the leaf spring may be configured so that, in the state where a force in the thickness direction is not applied to the leaf spring, the surface of the leaf spring having a projection is disposed on substantially the same plane as the surface of the cover body.

Surface 24b′ is one example of the surface of the cover body. Each of surface 38′, surface 40′, and surface 28A′ is one example of the surface of the leaf spring.

For example, in the configuration example shown in the first exemplary embodiment, the following configuration is employed as discussed above:
in a state where a force in the thickness direction is not applied to each of the plurality of leaf spring 28a to leaf spring 28h, the surface of each of leaf spring 28a to leaf spring 28h is disposed on substantially the same plane as the surface of each of second body 24b to fifth body 24e.

Thus, each of the plurality of projection 30a to projection 30h projects upward (in the Z-axis direction) from the surface of each of second body 24b to fifth body 24e. Therefore, when shield cover 12 is disposed near chassis 8, each of the plurality of projection 30a to projection 30h can be made to abut on chassis 8 and can be pressed down. Thus, each of the plurality of leaf spring 28a to leaf spring 28h can be elastically bent downward (in the minus direction on the Z-axis). Furthermore, in this state, the interval between shield cover 12 and chassis 8 can be made relatively short. Therefore, the size of shield structure 6 can be kept comp act.

In this shield cover, the leaf spring may include an expanded portion including a projection, and a connection portion that includes a first end connected to the cover body and a second end connected to the expanded portion, and extends in a predetermined direction from the first end to the second end. The width of the expanded portion in the direction substantially perpendicular to the predetermined direction may be greater than the width of the connection portion in the direction substantially perpendicular to the predetermined direction.

For example, in the configuration example shown in the first exemplary embodiment, the following configuration is employed as discussed above:
width W2 of expanded portion 40 in the direction substantially perpendicular to the predetermined direction is greater than width W1 of connection portion 38 in the direction substantially perpendicular to the predetermined direction.
   Thus, the spring property of each of the plurality of leaf spring 28a to leaf spring 28h can be improved.

This shield cover may include a pair of leaf springs, and the arrangement interval between the projections of each of the pair of leaf springs may be shorter than the quarter wavelength of the signal of a predetermined frequency used in the electronic components.

For example, in the configuration example shown in the first exemplary embodiment, the following configuration is employed as discussed above:
arrangement interval D between projection 30a and projection 30b of the pair of leaf spring 28a and leaf spring 28b is set to be shorter than the quarter wavelength (for example, 75 mm) of a signal of a predetermined frequency (for example, 1 GHz) used in each of the plurality of IC 16a to IC 16e.
   Thus, each of the plurality of leaf spring 28a to leaf spring 28h serves as an antenna, and the emission of electromagnetic waves from each of the plurality of leaf spring 28a to leaf spring 28h can be suppressed.

In the shield cover, each projection may be formed in a substantially hemispherical shape.

For example, in the configuration example shown in the first exemplary embodiment, each of the plurality of projection 30a to projection 30h is formed in a substantially hemispherical shape, as discussed above. Thus, in forming shield cover 12 by press work, each of the plurality of projection 30a to projection 30h can be easily formed.

Furthermore, the interval between shield cover 12 and chassis 8 sometimes changes in accordance with the type or the like of electronic apparatus 2, for example. Even in such a case, shield cover 12 can be formed by press work in the following manner:
while keeping constant the length in the predetermined direction of connection portion 38 of each of the plurality of leaf spring 28a to leaf spring 28h, the height in the Z-axis direction of each of the plurality of projection 30a to projection 30h is set at a height corresponding to the interval between shield cover 12 and chassis 8.
   Thus, by keeping constant the length in the predetermined direction of connection portion 38 of each of the plurality of leaf spring 28a to leaf spring 28h, for example, arrangement interval D between projection 30a and projection 30b of the pair of leaf spring 28a and leaf spring 28b can be kept shorter than the quarter wavelength, for example. In forming shield cover 12 by press work, the press work is performed more easily in a method of changing the height in the Z-axis direction of each of the plurality of projection 30a to projection 30h than in a method of changing the length in the predetermined direction of connection portion 38 of each of the plurality of leaf spring 28a to leaf spring 28h.

This electronic apparatus may include a first thermal conductive member sandwiched between an electronic component and the cover body, and a second thermal conductive member sandwiched between the cover body and the chassis.

Thermal conductive rubber 42 is one example of the first thermal conductive member, and thermal conductive rubber 44 is one example of the second thermal conductive member.

For example, in the configuration example shown in the first exemplary embodiment, the following configuration is employed as discussed above:
thermal conductive rubber 42 is sandwiched between IC 16a and first body 24a, and thermal conductive rubber 44 is sandwiched between first body 24a and chassis 8.
   Thus, the heat generated by IC 16a is transferred to shield cover 12 via thermal conductive rubber 42, and transferred to chassis 8 via thermal conductive rubber 44. As a result, the heat coming from IC 16a can be radiated through shield cover 12 and chassis 8, and the heat radiation effect can be improved.

In this electronic apparatus, the shield cover may include an attachment portion that is disposed on a cover body and attaches the cover body to a ground potential portion on the substrate. A leaf spring may be disposed near the attachment portion.

Each of attachment portion 26a to attachment portion 26j is one example of the attachment portion.

For example, in the configuration example shown in the first exemplary embodiment, the following configuration is employed as discussed above:
each of the plurality of leaf spring 28a to leaf spring 28h is disposed near any one of the plurality of attachment portion 26a to attachment portion 26j. Thus, the impedance between each of the plurality of leaf spring 28a to leaf spring 28h and ground wiring 14 can be reduced.

### Another Exemplary Embodiment

Thus, the first exemplary embodiment and the modified example have been described as examples of a technology disclosed in the present application. However, the disclosed technology is not limited to this, and can be also applied to exemplary embodiments having undergone modification, replacement, addition, or omission. A new exemplary embodiment may be created by combining the components described in the first exemplary embodiment and the modified example.

Another exemplary embodiment is described hereinafter.

In the first exemplary embodiment, electronic apparatus 2 is described as a liquid crystal TV receiver, but the present disclosure is not limited to this. Electronic apparatus 2 may be any electronic apparatus as long as the electronic apparatus includes an electronic component emitting electromagnetic waves, such as a Blu-ray (registered trademark) recorder, a personal computer, a tablet, or a smartphone, for example.

The first exemplary embodiment has described the configuration example in which each of the plurality of projection 30a to projection 30h is formed in a substantially hemispherical shape. However, the present disclosure is not limited to this. Each of the plurality of projection 30a to projection 30h may have any shape as long as the shape has a projection, for example, a substantially cylindrical shape. For example, when each of the plurality of projection 30a to projection 30h is formed in a substantially cylindrical shape, the contact area between each of the plurality of projection 30a to projection 30h and chassis 8 can be increased. Thus, the heat generated by IC 16a can be efficiently transferred from shield cover 12 to chassis 8.

The first exemplary embodiment has described the configuration example in which, in the state where a force in the thickness direction is not applied to leaf spring 28a, surface 38′ of connection portion 38 and surface 40′ of expanded portion 40 are disposed on substantially the same plane as surface 24b′ of second body 24b. However, the present disclosure is not limited to this. For example, leaf spring 28a may be disposed so that, in the state where a force in the thickness direction is not applied to leaf spring 28a, leaf spring 28a extends obliquely upward with respect to surface 24b′ of second body 24b. Each of other leaf spring 28b to leaf spring 28h may be disposed similarly.

Thus, the exemplary embodiments have been described as examples of the technology of the present disclosure. For that purpose, the accompanying drawings and the detailed descriptions are provided.

Therefore, the components shown in the accompanying drawings and the detailed descriptions can include not only components essential for solving problems, but also components that are used for exemplifying the technology but are not essential for solving problems. Therefore, just because these non-essential components are included in the accompanying drawings and the detailed descriptions, the non-essential components should not be determined to be essential.

The above-mentioned exemplary embodiments are described for exemplifying the technology of the present disclosure, so that various modifications, replacements, additions, or omissions can be performed within the scope or equivalent scope of the claims.

### INDUSTRIAL APPLICABILITY

The present disclosure is applicable to a shield cover for blocking electromagnetic waves emitted from an electronic component included in an electronic apparatus. For example, the present disclosure is applicable to a shield cover for blocking electromagnetic waves emitted from an IC mounted on a substrate included in an electronic apparatus. Specifically, the present disclosure is applicable to a general electronic apparatus including an electronic component emitting electromagnetic waves, such as a liquid crystal TV receiver, a Blu-ray (registered trademark) recorder, a personal computer, a tablet, or a smartphone.

### REFERENCE MARKS IN THE DRAWINGS

2 electronic apparatus
4 casing
6 shield structure
8 chassis
10 substrate
12, 12A shield cover
14 ground wiring
16a, 16b, 16c, 16d, 16e IC
18a, 18b, 18c, 18d, 18e, 18f, 18g, 18h, 18i, 18j contact clip
20, 22 clip portion
24, 24A cover body
24a first body
24b second body
24b′, 28A′, 38′, 40′ surface
24c third body
24d fourth body
24e fifth body
26a, 26b, 26c, 26d, 26e, 26f, 26g, 26h, 26i, 26j attachment portion
28a, 28b, 28c, 28d, 28e, 28f, 28g, 28h, 28A leaf spring
28Aa, 38a first end
28Ab, 38b second end
30a, 30b, 30c, 30d, 30e, 30f, 30g, 30h, 30A projection
32, 34, 36 cutout
38 connection portion
40 expanded portion
42 thermal conductive rubber
44 thermal conductive rubber

1. A shield cover for blocking an electromagnetic wave emitted from an electronic component, the shield cover comprising:
a cover body formed of a metal plate and covering the electronic component;
a leaf spring formed by cutting a part of the cover body; and
a projection disposed on the leaf spring and projecting in a thickness direction of the leaf spring.

2. The shield cover according to claim 1, wherein
in a state where a force in the thickness direction is not applied to the leaf spring, a surface of the leaf spring is disposed on substantially the same plane as a surface of the cover body, the surface of the leaf spring having the projection.

3. The shield cover according to claim 1, wherein
the leaf spring includes:
an expanded portion including the projection; and
a connection portion including a first end connected to the cover body and a second end connected to the expanded portion, and extending in a predetermined direction from the first end to the second end, and
a width of the expanded portion in a direction substantially perpendicular to the predetermined direction is greater than a width of the connection portion in the direction substantially perpendicular to the predetermined direction.

4. The shield cover according to claim 1, wherein
the shield cover comprises a pair of the leaf springs, and
an arrangement interval between the projections respectively disposed on the pair of leaf springs is shorter than a quarter wavelength of a signal of a predetermined frequency used in the electronic component.

5. The shield cover according to claim 1, wherein
the projection is formed in a substantially hemispherical shape.

6. An electronic apparatus comprising:
a metal chassis;
a substrate disposed so as to face the chassis;
an electronic component mounted on the substrate; and
a shield cover disposed between the chassis and the substrate, and for blocking an electromagnetic wave emitted from the electronic component,
wherein the shield cover includes:
a cover body formed of a metal plate, and mounted on the substrate so as to cover the electronic component;
a leaf spring formed by cutting a part of the cover body; and
a projection disposed so as to project from the leaf spring toward the chassis, and abutting on the chassis.

7. The electronic apparatus according to claim 6, further comprising:
a first thermal conductive member sandwiched between the electronic component and the cover body; and
a second thermal conductive member sandwiched between the cover body and the chassis.

8. The electronic apparatus according to claim 6, wherein
the shield cover includes an attachment portion disposed on the cover body and attaching the cover body to a ground potential portion on the substrate, and
the leaf spring is disposed near the attachment portion.
